(19) United States
(12) Patent Application Publication
(10) Pub. No.: US 2009/0200538 A1
(43) Pub. Date: Aug. 13, 2009

(54) Group lll-V compound semiconductor and a method for producing the same

(75) Inventors: Makoto Sasaki, Ibaraki (JP); Tomoyuki Takada, Ibaraki (JP)

Correspondence Address: FITCH, EVEN, TABIN & FLANNERY, P. O. BOX 18415, WASHINGTON, DC, 20036, US

(73) Assignee: Sumitomo Chemical Company, Limited, Tokyo (JP)

(21) Appl. No.: 11/663,638

(22) PCT Filed: Sep. 21, 2005
(86) PCT No.: PCT/JP05/17916

§ 371 Date: Mar. 23, 2007

(30) Foreign Application Priority Data
Sep. 28, 2004 (JP) 2004-281053

(51) Int. Cl. H01L 31/00; H01L 33/00; H01L 21/00; H01L 21/20

(52) U.S. Cl. 257/14; 257/103; 438/46; 438/483; 257/E33.001; 257/E31.001; 257/E21.001

(57) ABSTRACT

A Group III-V compound semiconductor includes an n-type layer, a p-type layer, a p-type layer represented by a formula InₐGa_{b}Al_{c}N, having a thickness of not less than 300 nm, and a multiple quantum well structure which exists between the n-type layer and the p-type layer, has at least two quantum well structures including two barrier layers and a quantum well layer represented by a formula InₓGa_{y}Al_{z}N between the barrier layers; and a ratio of R/α of not more than 42.5%, wherein R is an average mole fraction of indium nitride in the quantum well layer, which is measured by X-ray diffraction, and α is a mole fraction of indium nitride calculated from a wavelength of light emitted from the group III-V compound semiconductor due to current injection.

### TECHNICAL FIELD

The present invention relates to a group III-V compound semiconductor having a p-type layer represented by a formula InₐGa_{b}Al_{c}N (a+b+c=1, 0≦a<1, 0<b≦1, 0≦c<1) and a quantum well structure including barrier layers and a quantum well layer represented by a formula InₓGa_{y}Al_{z}N (x+y+z=1, 0<x<1, 0<y<1, 0≦z<1) between the barrier layers.

### BACKGROUND ART

A group III-V compound semiconductor represented by a formula In_{d}GaₑAl_{f}N (d+e+f=1, 0≦d≦1, 0≦e≦1, 0≦f≦1) is currently used as a light-emitting device which emits colors of green, blue, violet or ultra violet.

The white-light-emitting devices combined with light-emitting materials and fluorescent materials have been studied to apply to backlights or lightning. Since specific crystals containing indium nitride, for example, enable to change the wavelength of light emission by changing indium nitride (InN) mole fraction thereof, they are useful as a display device or a light source exciting fluorescent material.

There have been efforts to grow a layer of the group III-V compound semiconductor on various substrates composed of substances such as sapphire, GaAs and ZnO. However, since the lattice constant and chemical characteristics of substrates are quite different from that of the compound semiconductor, crystals sufficiently satisfying high quality have not yet been produced. It has been proposed that a GaN crystal of which lattice constant and chemical characteristics are similar to that of a compound semiconductor is grown, followed by the compound semiconductor being grown thereon to obtain a light-emitting device (Japanese Examined Patent Publication No. S55-3834).

It has also been proposed that a compound semiconductor having a quantum well structure, represented by a formula InₓGa_{y}Al_{z}N (x+y+z=1, 0<x<1, 0<y<1, 0≦z<1) is grown to obtain a light-emitting device (Japanese Patent No. 3064891).

The light-emitting devices disclosed in these documents are not satisfied in viewpoint of brightness.

There is a known method that a InGaN layer is grown on a GaN doped with silicon at from 660 to 780° C. under from 100 to 500 Torr and the temperature was held for from 5 to 10 seconds, followed by growing the GaN, from thereon, InGaN layer and GaN are repeatedly grown under this condition to form a multiple quantum well structure, followed by a p-GaN layer being grown at 1040° C. to produce a compound semiconductor.

In this method, during growing a p-GaN layer, the InGaN layer is broken to precipitate indium metal or indium nitride crystal, resulting in significant deterioration of brightness (Journal of Crystal Growth, 248, 498, 2003).

### DISCLOSURE OF THE INVENTION

An object of the present invention is to provide a group III-V compound semiconductor which is suitable used as a light-emitting device with high brightness. Another object of the invention is to provide a method for producing the above group III-V compound semiconductor.

The present inventors have investigated a group III-V compound semiconductor, and resultantly leading to the completion of the present invention.

The present invention provides a group III-V compound semiconductor comprising:

an n-type layer,

a p-type layer represented by a formula InₐGa_{b}Al_{c}N (a+b+c=1, 0≦a<1, 0<b≦1, 0≦c<1), having a thickness of not less than 300 nm, and

a multiple quantum well structure which exists between the n-type layer and the p-type layer, and has at least two quantum well structures including two barrier layers and a quantum well layer represented by a formula InₓGa_{y}Al_{z}N (x+y+z=1, 0<x<1, 0<y<1, 0≦z<1) between the barrier layers; and

a ratio of R/α of not more than 42.5%, wherein R is an average mole fraction of indium nitride (InN) in the quantum well layer, which is measured by X-ray diffraction, and a is a mole fraction of indium nitride (InN) calculated from α wavelength of light emitted from the group III-V compound semiconductor due to current injection.

The present invention provides a group III-V compound semiconductor comprising:

an n-type layer,

a p-type layer represented by a formula InₐGa_{b}Al_{c}N (a+b+c=1, 0≦a<1, 0<b≦1, 0≦c≦1), having a thickness of not less than 300 nm and

a single quantum well structure which exists between the n-type layer and the p-type layer, and has two barrier layers and a quantum well layer represented by a formula InₓGa_{y}Al_{z}N (x+y+z=1, 0<x<1, 0<y<1, 0≦z<1) between the barrier layers; and

a ratio of R/α of not more than 42.5%,

wherein R is an average mole fraction of indium nitride (InN) in the quantum well layer, which is measured by X-ray diffraction, α is a mole fraction of indium nitride (InN) calculated from a wavelength of light emitted from the group III-V compound semiconductor due to current injection.

Further, the present invention provides a method for producing a group III-V compound semiconductor comprising an n-type layer, a p-type layer represented by a formula InₐGa_{b}Al_{c}N (a+b+c=1, 0≦a<1, 0<b≦1, 0≦c<1) and a quantum well structure which exists between the n-type layer and the p-type layer, and has a quantum well structure including at least two barrier layers and a quantum well layer by a formula InₐGa_{y}Al_{z}N (x+y+z=1, 0<x<1, 0<y<1, 0≦z<1) between the barrier layers, comprising steps of:

holding a quantum well layer at a growth temperature of the quantum well layer at a temperature being equal to or higher than the growth temperature of the quantum well layer to interrupt a crystal growth between growth completion of the quantum well layer and growth beginning of the barrier layer, and

growing a p-type layer having a thickness of 300 nm or more.

Furthermore, the present invention provides a group III-V compound semiconductor light-emitting device comprising the group III-V compound semiconductor described above.

### BRIEF DESCRIPTION OF THE DRAWINGS

FIG. 1 illustrates the structure of an embodiment of the group III-V compound semiconductor of the present invention.

### EXPLANATION OF REFERENCE LETTERS OR NUMERALS

1 n-type GaN layer
2 undoped GaN layer
3 GaN layer
4 InGaN quantum well layer
5 GaN barrier layer
6 GaN cap layer
7 Mg-doped AlGaN cap layer
8 p-type GaN layer
9 n electrode
10 p electrode

### DETAILED DESCRIPTION OF PREFERRED EMBODIMENT OF THE INVENTION

### Group III-V Compound Semiconductor

The group III-V compound semiconductor of the present invention has an n-type layer and a p-type layer.

The p-type layer is represented by the formula InₐGa_{b}Al_{c}N (a+b+c=1, 0≦a<1, 0<b≦, 0≦c<1) and has a thickness of 300 nm or more. When the thickness of the p-type layer is increased, the electrostatic discharge property of the group III-V compound semiconductor is enhanced. The thickness of the p-type layer is preferably 400 nm or more, more preferably 500 nm or more, further preferably 600 nm or more. Further, when the thickness of the p-type layer is 500 nm or more, the light output of the group III-V compound semiconductor is also enhanced. The group III-V compound semiconductor comprising the p-type layer having a thickness of 500 nm or more is preferably used as a light-emitting device excellent in its light output and electrostatic discharge property. On the contrary, when the thickness of the p-type layer is too thick, it causes warp of substrate or requires long time for production. The thickness of the p-type layer is usually 3 μm or less.

The p-type layer may be doped with a impurity. Examples of the impurity include Mg, Zn and Ca. The impurities may be singly or plurality used. The concentration of the impurity is usually from 1×10¹⁷ cm⁻³ to 1×10²¹ cm⁻³.

Further, the group III-V compound semiconductor has at least one quantum well structure. The quantum well structure includes a quantum well layer represented by a formula InₓGa_{y}Al_{z}N (x+y+z=1, 0<x<1, 0<y<1, 0≦z<1) and at least two barrier layers. The quantum well layer is between the barrier layers.

The quantum well structure may be used as a light-emitting layer of the light-emitting device or a substrate to improve the crystallinity by reducing dislocation and the like. The quantum well structure may be a single quantum well structure including a quantum layer and barrier layers or a multiple quantum well structure including at least two quantum well layers and barrier layers. When the quantum well structure is used as a light-emitting layer, a multiple quantum well structure is preferable in viewpoint of gaining high light output.

The quantum well layer has a thickness of usually 0.5 nm or more, preferably 1 nm or more, more preferably 1.5 nm or more, and usually 9 nm or less, preferably 7 nm or less, more preferably 6 nm or less.

The quantum well layer may be doped with a impurity or not. When the quantum well layer is used as a light-emitting layer, the undoped is preferable in viewpoint of gaining strong light emission with favorable color purity. In case the quantum well layer is doped with a impurity, since too high doping concentration possibly deteriorates crystallinity, the concentration is usually 10²¹ cm⁻³ or less, preferably 10¹⁹ cm⁻³ or less, more preferably 10¹⁷ cm⁻³ or less. Examples of the impurities include Si, Ge, S, O, Zn and Mg. The impurities may be singly or plurality doped.

The barrier layer is usually a group III-V compound represented by a formula In_{d}GaₑAl_{f}N (d+e+f=1, 0≦d<1, 0≦e≦1, 0≦f≦1). The two of barrier layers adjacent to the quantum well layer may be same or different.

The barrier layer has a thickness of usually 1 nm or more, preferably 1.5 nm or more, more preferably 2 nm or more, and usually 100 nm or less, preferably 50 nm or less, more preferably 20 nm or less.

The barrier layer may be doped with a impurity or not. Examples of the impurity include Si, Ge, S, O, Zn and Mg. The impurities may be singly or plurally doped. When the barrier layer is doped with the impurity, the concentration of the impurity is usually from 10¹⁷ cm⁻³ to 10²¹ cm⁻³. When the multiple quantum well structure is used as a light-emitting layer, some of the barrier layers may be doped with a impurity. By doping the impurity, it may be possible to control electro-conductive type of the barrier layer and to effectively inject electrons or holes. Since the impurity doping may deteriorate crystallinity of the light-emitting layer being adjacent to the doped barrier layer, barrier layer contacting with the quantum well layer not used as light-emission layer may be doped with the impurity.

When the group III-V compound semiconductor comprises the multiple quantum well structure, the multiple quantum well structure includes at least two quantum well layers having the same thickness and same composition; same thickness and different composition; different thickness and same composition; or different thickness and different composition. Further, the multiple quantum well structure includes at least two barrier layers having the same thickness and same composition; same thickness and different composition; different thickness and same composition; or different thickness and different composition. When the multiple quantum well structure is used as a light-emitting layer, the multiple quantum well structure preferably has at least two quantum well layers having the same thickness and same composition; and at least two barrier layers having the same thickness and same composition. The group III-V compound semiconductor having such thickness and composition emits a light with an enhanced color purity due to light emitted from at least two quantum well layers.

The group III-V compound semiconductor has a ratio of R/α of not more than 42.5%, preferably 40% or less, more preferably 35% or less, further preferably 30% or less.

R is an average mole fraction of indium nitride (InN) in the quantum well layer. Value of R may be measured by analyzing the quantum well structure using X-ray diffractometer.

When the group III-V compound semiconductor comprises the multiple quantum well structure, a mole fraction of InN (W) in the multiple quantum well structure is measured from a satellite reflection derived from superlattice of the multiple quantum well structure, and then R is calculated from according to value of W and the proportion of a thickness of the quantum well layer to that of the barrier layer.

When the group III-V compound semiconductor comprises the single quantum well structure, a mole fraction of InN (W) in the single quantum well structure is also measured by a X-ray diffraction.

In case the group III-V compound semiconductor having the quantum well layer doped with impurity of low concentration, for example, 10²¹ cm⁻³ or less, preferably 10¹⁹ cm⁻³ or less, more preferably 10¹⁷ cm⁻³ or less, and showing a band edge emission generated due to current injection, a may be calculated from the wavelength of light emitted due to current injection, according to the following procedures.

The wavelength λ (nm) of light emitted from a semiconductor used for light-emission devices is generally represented by the following equation when the band-gap energy of the semiconductor is let be Eg (eV).

λ=1240/Eg (1)

The band-gap energy of a semiconductor may be calculated from the mole fraction thereof. For example, in the case of In_{α}Ga_{1-α}N which is the mixed crystal of InN and GaN, since the band-gap energy of InN is 0.8 eV and that of GaN is 3.42 eV, the band-gap energy (Eg) of the semiconductor is represented as follows.

Eg=0.8α+3.42(1−α) (2)

Consequently, a of the group III-V compound semiconductor is calculated according to the equations (1) and (2).

α=[3.42−(1240/α)]/(3.42−0.8) (3)

When emitted-light wavelength is 470 nm, α is 0.298.

In case the group III-V compound semiconductor having the quantum well layer doped with impurity of high concentration and showing the light emission derived from the impurity level, α may be calculated from the energy value of the impurity level. For example, Journal of Vacuum Science and Technology A, Vol. 13(3), page 705 discloses that the energy level of Zn in a light-emitting diode having Zn- and Si-doped InGaN layer as a light-emitting layer is from 0.4 to 0.5 eV according to measuring from the peak wavelength of light emission.

The group III-V compound semiconductor may have a cap layer represented by a formula InᵢGaⱼAlₖN (i+j+k=1, 0≦i≦0≦j≦1, 0≦k≦1) between the quantum well layer and the p-type layer. The cap layer may be singly or plurally grown. In case a group III-V compound semiconductor includes AlN mixed crystal, the group III-V compound semiconductor has enhanced thermal stability, resulting in suppression of the thermal degradation such as phase separation of the light-emission layer. The cap layer may be doped with p-type dopant such as Mg, Zn and Ca or n-type dopant such as Si, O, S and Se.

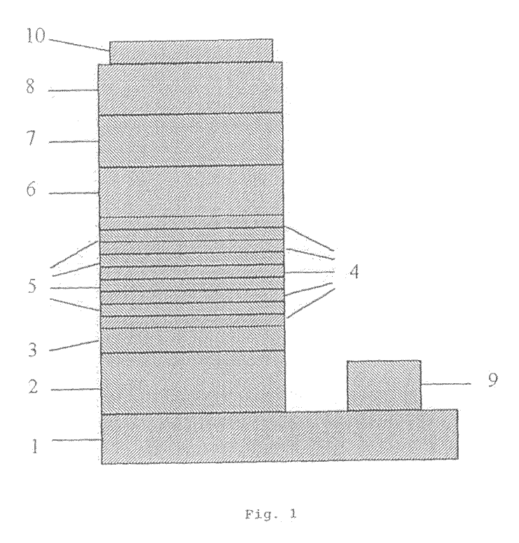

An embodiment of the device structure comprising the group III-V compound semiconductor described above is illustrated in FIG. 1.

The group III-V compound semiconductor illustrated in FIG. 1 comprises following layers from 1 to 8 in the following order;
an n-type GaN layer 1,
an undoped GaN layer 2 mounted on the n-type GaN layer 1,
a multiple quantum well structure including
a GaN layer 3 functioning as a barrier layer,
an InGaN layers 4 functioning as a quantum well layer and a GaN layers 5 functioning as a barrier layer alternately layered in cycle of 5 times,
a GaN layer 6
an AlGaN layer 7 doped with Mg and
a p-type GaN layer 8; and
   an n electrode 9 and
   a p electrode 10 mounted on the p-type GaN layer 8. Application of voltage to the p-n junction of device in forward direction subjects the injected electrons and holes to recombination each other in the multiple quantum well layer, allowing the device to emit light.

### Production of the Group III-V Compound Semiconductor

The group III-V compound semiconductor may be advantageously produced by a metal organic chemical vapor deposition (herein after abbreviated as MOCVD), a molecular beam epitaxy (hereinafter abbreviated as MBE), a hydride vapor phase epitaxy (hereinafter abbreviated as HVPE), preferably MOCVD. The MOCVD is excellent in terms of homogeneity of layer, steepness of interface and mass-production ability. Crystal growth may be carried out by using a commercially available apparatus.

The group III-V compound semiconductor may be usually produced by a method of supplying raw materials into substrate in a reactor.

Examples of substrate used in the production of the group III-V compound semiconductor include sapphire, ZnO, metal boride (ZrB₂), SiC, GaN and AlN. These substrates may be used singly or two or more of them may be used in combination.

Examples of a raw material for group III element include trialkylgallium represented by a general formula R₁R₂R₃Ga (, wherein R₁, R₂ and R₃ represent lower alkyl groups) such as trimethylgallium (TMG) and triethylgallium (TEG); trialkylaluminum represented by a general formula R₁R₂R₃Al (, wherein R₁, R₂ and R₃ represent lower alkyl groups) such as trimethylaluminum (TMA), triethylaluminum (TEA) and triisobutylaluminum; trimethylaminealane [(CH₃)3N:AlH₃], trialkylindium represented by a general formula R₁R₂R₃In (, wherein R₁, R₂ and R₃ represent lower alkyl groups) such as trimethylindium (TMI) and triethylindium;

a compound such as diethylindium chloride in which 1 to 3 alkyl groups of trialkylindium are replaced with halogen elements; and indium halide represented by a general formula InX (, wherein X represents halogen element) such as indium chloride. These raw material may be used singly or two or more of them may be used in combination.

Examples of a raw material for group V elements include ammonia, hydrazine, methylhydrazine, 1,1-dimethylhydrazine, 1,2-dimethylhydrazine, t-butylamine and ethylenediamine; preferably ammonia and hydrazine. Ammonia and hydrazine do not contain carbon atoms in molecules, and prevent semiconductors from carbon contamination. These raw material may be used singly, or two or more of them may be used in combination.

The quantum well structure having the foregoing ratio of R/α may be grown by a heat treatment. Growth of the quantum well layer is carried out usually at 650° C. to 850° C. in a reactor. Growth of the barrier layer is carried out usually at, 650° C. to 1000° C. in a reactor.

In the production method of the present invention, the quantum well layer is held at a temperature being equal to or higher than the growth temperature of the quantum well layer to interrupt a crystal growth between growth completion of the quantum well layer and growth beginning of the barrier layer.

In case a quantum well layer is held at the temperature of growing quantum well layer, the retention time is usually 10 minutes or more, preferably 15 minutes or more, and usually 60 minutes or less. The pressure is usually more than 30 kPa. In case of a pressure of 20 kPa or less, retention time is preferably from 1 to 5 minutes.

In case a quantum well layer is held at the temperature higher than the temperature of growing quantum well layer, the minimum temperature is 10° C. being equal to and higher than the temperature of growing quantum well layer, more preferably not lower than 30° C., further preferably not lower than 50° C., and maximum temperature is 100° C. more less than the temperature of growing quantum well layer. The retention time varies depending on the temperature, being usually 1 minute or more, preferably 3 minutes or more, more preferably 5 minutes or more, further preferably 7 minutes or more, and usually 60 minutes or less. It is preferable the holding time is equal to an interval for raising temperature from the completion of quantum well layer growth to the beginning of barrier layer growth.

In the holding step, a raw material for group III elements is usually not supplied into the reactor. On the contrary, a raw material for group V elements and carrier gas may be supplied or not. In viewpoint of preventing reduced concentration of nitrogen in the quantum well layer, a raw material for group V elements is preferably supplied into the reactor.

After growth of the quantum well structure, the p-type layer having a thickness of 300 nm or more is grown. The temperature of growing the p-type layer is usually from 700 to 1100° C. In case a group III-V compound semiconductor has p-type layer represented by a formula In_{g}GaₕN (g+h=1, 0<g≦1, 0≦h<1), the p-type layer is preferably grown at relatively low temperature such as from 650 to 950° C. and thus a quantum well layer is prevented from thermal degradation during the growth of p-type layer.

After completion of growth of the p-type layer, the group III-V compound semiconductor may be subjected to annealing to obtain favorable contact resistance with an electrode before or after the electrode formation. The atmosphere for annealing may be an inert gas or a gas substantially containing hydrogen, or such atmospheric gases may be added with a gas containing oxygen. These gases may be used singly or two or more of them may be used in combination. The temperature for annealing is 200° C. or more, preferably 400° C. or more.

Holding step and growing step may be carried out using a conventional reactor. The reactor is equipped with a feeding member which can supply a raw material to substrate from upper side thereof, or side thereof. In the reactor the substrate is placed almost upside-up; as alternation, upside-down. In case the substrate is placed upside-down, a raw material may be supplied from a lower side of substrate or a side of substrate. The angle of the substrate in the reactor is not necessarily exactly horizontal, may be almost or completely vertical.

The production of the group III-V compound semiconductor may be carried out under conventional conditions except that of the holding step and the growing step of p-type layer. In case quantum well layer, barrier layer or p-type layer is doped with impurity, the impurity is preferably supplied in a form of organic metal.

The production of the group III-V compound semiconductor may be carried out using an apparatus, which can simultaneously grow layers on plural substrates, arranged with substrates and feeding members. Regarding supplying raw materials, the raw materials for group III elements and that for group V elements may be introduced from sources, respectively and mixed before being supplied into a reactor in order to avoid pre-reaction between the raw materials.

### EXAMPLE

The present invention is described in more detail by following Examples, which should not be construed as a limitation upon the scope of the present invention.

### Example 1

The low-temperature-grown GaN buffer layer was grown on C-face sapphire at 490° C. supplying TMG and ammonia as the raw materials and hydrogen as the carrier gas.

After TMG supply being once ceased, the temperature was raised up to 1090° C. and then TMG, ammonia and silane as the raw materials and hydrogen as the carrier gas were supplied to grow an n-type GaN layer having a thickness of 3 μm, followed by supply of silane being ceased to grow an undoped GaN layer having a thickness of 300 nm. After ceasing supply of TMG and silane and then being cooled down to 785° C., TEG and ammonia as the raw materials and nitrogen as the carrier gas were supplied to grow a GaN layer having a thickness of 100 nm, and then followed by repeating the procedure 5 times, the procedure that TEG, TMI and ammonia as the raw materials and nitrogen as the carrier gas were supplied under the pressure of 50 kPa to grow a InGaN layer having a thickness of 3 nm and a GaN layer having a thickness of 15 nm. The detail of this growing procedure was as follows: ammonia, TEG and TMI were supplied to grow a InGaN layer in 3 nm thickness; then supply of TEG and TMI was ceased, followed by only the ammonia and the carrier gas being supplied to hold for 15 minutes; and then an undoped GaN layer being grown in 15 nm thickness.

After this procedure being cycled 5 times, TEG and ammonia were continuously supplied to grow an undoped GaN layer having a thickness of 3 nm, resulting in the final thickness of the undoped GaN layer being 18 nm. Thereafter, TEG supply was ceased, and then the temperature was raised up to 940° C., followed by TEG, TMA, ammonia and bisethylcyclopentadienyl magnesium as a source for p-type dopant being supplied to grow a magnesium-doped AlGaN layer having a thickness of 30 nm. After supply of TEG, TMA and bisethylcyclopentadienyl magnesium being ceased, the temperature was raised up to 1010° C., followed by TMG, ammonia and bisethylcyclopentadienyl magnesium as a source for p-type dopant being supplied to grow a p-type GaN layer having a thickness of 600 nm.

After an obtained group III-V compound semiconductor obtained was subjected to etching, a p electrode of NiAu and an n electrode of Al were formed to obtain a LED.

The LED was applied with current of 20 mA in forward direction, every sample exhibited clear blue light emission. The brightness was 6028 mcd and the peak wavelength of light emission was 473 nm. According to the light-emission wavelength, the mole fraction of InN (α) was calculated as 30.4% according to the equations (3) described above.

According to the evaluation regarding the satellite reflection of the multiple quantum well structure determined by X-ray diffraction, the mole fraction of InN (W) was 1.93% in terms of average value of the whole multiple quantum well structure, this resulted that the mole fraction of InN(R) was 11.58%. The ratio of R/α was 38.1%.

The LED was estimated by an electrostatic discharge test and had an electrostatic discharge breakdown voltage in reverse direction of 225 V. The results are also shown in Table 1.

### Example 2

An LED was obtained by the same operation as in Example 1 except the thickness of the p-type GaN layer changed to 450 nm. The LED was estimated under the same conditions as that of Example 1. The results are shown in Table 1.

### Example 3

An LED was obtained by the same operation as in Example 1 except the thickness of the p-type GaN layer changed to 300 nm. The LED was estimated under the same conditions as that of Example 1. The results are shown in Table 1.

### Reference 1

An LED was obtained by the same operation as in Example 1 except the thickness of the p-type GaN layer changed to 150 nm. The LED was estimated under the same conditions as that of Example 1. The results are shown in Table 2.

### Comparative Example 1

An LED was obtained by the same operation as in Reference 1 except the holding step was not conducted after the growth of the InGaN layer, and the GaN layer was successively grown. The LED was estimated under the same conditions as that of Example 1. The results are shown in Table 2.

### Comparative Example 2

An LED was obtained by the same operation as in Example 1 except the holding step was not conducted after the growth of the InGaN layer, and the GaN layer was successively grown. The LED was estimated under the same conditions as that of Example 1. The results are shown in Table 2.

TABLE 1

| | Example | Example | Example |
|---|---|---|---|
| | 1 | 2 | 3 |
| Thickness of p-type | 600 | 450 | 300 |
| layer (nm) | | | |
| Brightness (mcd) | 6028 | 3472 | 2496 |
| Wave length at peak | 473 | 473 | 469 |
| intensity λ (nm) | | | |
| Mole fraction α | 30.4 | 30.5 | 29.6 |
| (%) | | | |
| Average mole fraction | 1.93 | 1.92 | 1.96 |
| (%) | | | |
| Mole fraction R (%) | 11.58 | 11.52 | 11.73 |
| Ratio of R/α (%) | 38.1 | 37.8 | 39.6 |
| Electrostatic | 225 | 140 | 88 |
| discharge breakdown | | | |
| voltage(V) | | | |

TABLE 2

| | Reference | Compara. | Compara. |
|---|---|---|---|
| | 1 | Ex. 2 | Ex. 3 |
| Thickness of p-type | 150 | 150 | 600 |
| layer (nm) | | | |
| Brightness (mcd) | 4089 | 1844 | 1120 |
| Wave length at peak | 474 | 450 | 445 |
| intensity λ (nm) | | | |
| Mole fraction α | 30.4 | 25.4 | 24.3 |
| (%) | | | |
| Average mole fraction | 1.96 | 2.89 | 2.97 |
| (%) | | | |
| Mole fraction R (%) | 11.73 | 17.34 | 17.79 |
| Ratio of R/α (%) | 38.3 | 68.3 | 73.2 |
| Electrostatic | 83 | 75 | 180 |
| discharge breakdown | | | |
| voltage(V) | | | |

### INDUSTRIAL APPLICABILITY

By using the group III-V compound semiconductor of the present invention, a light-emitting device with high brightness and excellent electrostatic discharge property is provided.

By using the method for producing the group III-V compound semiconductor of the present invention, the light-emitting device described above is easily produced.

1. A group III-V compound semiconductor comprising:
an n-type layer,
a p-type layer represented by a formula InₐGa_{b}Al_{c}N, wherein a+b+c=1, 0≦a≦1, 0≦b≦1, 0≦c≦1, having a thickness of not less than 300 nm, and
a multiple quantum well structure which exists between the n-type layer and the p-type layer, and has at least two quantum well structures including two barrier layers and a quantum well layer represented by a formula InₐGa_{y}Al_{c}N, wherein x+y+z=0, 0≦x≦1, 0≦y≦1, 0≦z≦1 between the barrier layers; and
a ratio of R/α of not more than 42.5%, wherein R is an average mole fraction of indium nitride (InN) in the quantum well layer, which is measured by X-ray diffraction, a is a mole fraction of indium nitride (InN) calculated from a wavelength of light emitted from the group III-V compound semiconductor due to current injection.

2. A group III-V compound semiconductor comprising:
an n-type layer,
a p-type layer represented by a formula InₐGa_{b}Al_{c}N wherein a+b+c=1, 0≦a≦1, 0≦b≦1, 0≦c≦1, having a thickness of not less than 300 nm and
a single quantum well structure which exists between the n-type layer and the p-type layer, and has two barrier layers and a quantum well layer represented by a formula InₓGa_{y}Al_{z}N, wherein x+y+z=1, 0≦x≦1, 0≦y≦1, 0≦z≦1, between the barrier layers; and
a ratio of R/α of not more than 42.5%, wherein R is an average mole fraction of indium nitride (InN) in the quantum well layer, which is measured by X-ray diffraction, a is a mole fraction of indium nitride (InN) calculated from a wavelength of light emitted from the group III-V compound semiconductor due to current injection.

3. A method for producing a group III-V compound semiconductor comprising an n-type layer, a p-type layer represented by a formula InₐGa_{b}Al_{c}N wherein a+b+c=1, 0≦a<1, 0≦b≦1, 0≦c≦1, and a quantum well structure which exists between the n-type layer and the p-type layer, and has a quantum well structure including at least two barrier layers and a quantum well layer by a formula InₓGa_{y}Al_{z}N, wherein x+y+z=1, 0≦x≦1, 0≦y≦1, 0≦z≦1, between the barrier layers, comprising steps of:
holding the quantum well layer between completion of the quantum well layer growth and beginning of the barrier layer growth, at a temperature of growing the quantum well layer at a temperature being equal to or higher than the temperature of growing the quantum well layer, and
growing a p-type layer to be total thickness of the group III-V compound semiconductor of 300 nm or more.

4. The method according to claim 3, wherein the holding step is carried out without supplying a raw material for group III elements.

5. A group III-V compound semiconductor light-emitting device comprising the group III-V compound semiconductor according to claim 1.

6. A group III-V compound semiconductor light-emitting device comprising the group III-V compound semiconductor according to claim 2.
